(19) United States
(12) Patent Application Publication
(10) Pub. No.: US 2012/0261693 A1
(43) Pub. Date: Oct. 18, 2012

(54) LIGHT-EMITTING DIODE DEVICE

(75) Inventor: Kuan-Qun Chen, Tainan (TW)

(73) Assignee: CHI MEI LIGHTING TECHNOLOGY CORP., Tainan (TW)

(21) Appl. No.: 13/206,925

(22) Filed: Aug. 10, 2011

(30) Foreign Application Priority Data
Apr. 15, 2011 (TW) 100113214

(51) Int. Cl. H01L 33/60

(52) U.S. Cl. 257/98; 257/E33.075

(57) ABSTRACT

A light-emitting diode device. In one embodiment, the light-emitting device includes a heat-dissipating mount and a light-emitting diode chip. The heat-dissipating mount has a cavity, wherein the cavity includes an embedded portion and an inclined surface connected with the embedded portion. The light-emitting diode chip includes a substrate partly embedded into the embedded portion. A lower region of a side surface of the substrate has a first unsmooth surface, the first unsmooth surface has an exposed portion protruding above the embedded portion, and a bottom edge of the lower region is connected to a bottom surface of the substrate.

### CROSS-REFERENCE TO RELATED PATENT APPLICATION

This non-provisional application claims priority under 35 U.S.C. §119(a) on Patent Application No. 100113214 filed in Taiwan, R.O.C. on Apr. 15, 2011, the entire contents of which are hereby incorporated by reference.

### FIELD OF THE INVENTION

The present invention relates to a light-emitting device, and more particularly to a light-emitting diode (LED) device.

### BACKGROUND OF THE INVENTION

As the LED is applied in high-luminance products like illuminators and headlights of vehicles, the operating power of the LED chip also increases accordingly. However, about 80% of the electric power input in an LED chip is transformed into heat energy and only 20% is transformed into light energy. Therefore, the high power LED chip generates more and more heat, which leads to higher and higher heat dissipation requirement of the LED chip.

FIG. 1 is a sectional view of a conventional LED device. An LED device 100 is disclosed in the related art, which includes a metal heat dissipation base 102 for solving the heat dissipation requirement of the LED chip 106. In the LED device 100, the metal film 104 is disposed on a surface of the metal heat dissipation base 102. The LED chip 106 is partially embedded in the metal film 104 so as to be fixed on the metal heat dissipation base 102. Electrode pads 122 and 128 are respectively disposed on the metal films 104 on two sides of the LED chip 106 through adhesive layers 116.

The LED chip 106 includes a substrate 110, a light emitting epitaxial structure 108 and two electrodes 112 and 114. The light emitting epitaxial structure 108 is disposed on the substrate 110 and the electrodes 112 and 114 are disposed on the light emitting epitaxial structure 108. On the other hand, the electrode pad 122 includes an insulating layer 118 and a conductive layer 120, in which the conductive layer 120 is disposed on the insulating layer 118. Likewise, the electrode pad 128 includes an insulating layer 124 and a conductive layer 126, in which the conductive layer 126 is disposed on the insulating layer 124.

In the LED device 100, the electrode 112 of the LED chip 106 and the conductive layer 120 of the electrode pad 122 are connected through a conductive wire 130 and the electrode 114 of the LED chip 106 and the conductive layer 126 of the electrode pad 128 are connected through a conductive wire 132 in a wire bonding manner.

In the architecture of a conventional LED device 100, as a major part of the LED chip 106 is embedded in the metal film 104 on the metal heat dissipation base 102, the heat generated by the LED chip 106 in operation may be conducted and further dissipated through the metal film 104 and the metal heat dissipation base 102 below. Therefore, this heat dissipation design may greatly improve the heat dissipation efficacy of the LED device 100.

However, the luminous layer in the light emitting epitaxial structure 108 of the LED chip 106 is not embedded into the metal film 104. Since a major part of the substrate 110 of the LED chip 106 is embedded into the metal film 104, most of the light emitted by the luminous layer of the light emitting epitaxial structure 108 towards the substrate 110 below is confined within the LED chip 106 due to the opaque feature of the metal films 104 on the sides of the substrate 110. For example, the light emitted by the luminous layer of the light emitting epitaxial structure 108 may be reflected multiple times within the substrate 110 and cannot be successfully emitted out of the LED chip 106 or severe energy loss might occur, which greatly reduces the intensity of the emitted light. As such, the light extraction efficiency of the LED chip 106 is reduced, thus resulting in the apparent decrease of the luminous efficiency.

Furthermore, the design of the electrode pads 122 and 128 emitted from the metal film 104 may influence the side light of the LED chip 106, and thus reduces the overall luminance of the LED device 100.

Therefore, a heretofore unaddressed need exists in the art to address the aforementioned deficiencies and inadequacies.

### SUMMARY OF THE INVENTION

Accordingly, an aspect of the present invention is directed to an LED device, in which a non-smooth surface at a side of the substrate of the LED chip is not completely embedded in the heat dissipation base below and an exposed part is emitted from the embedded surface. In this manner, the light emitted downward by the epitaxial structure may be successfully emitted to the outside from the side of the substrate. Therefore, the overall luminance of the LED device can be effectively improved.

Another aspect of the present invention is directed to an LED device, in which a lower region, a middle region and/or an upper region of a side surface of the substrate of the LED chip have non-smooth surfaces, so the light emitted by the epitaxial structure may be emitted through the middle region and/or the upper region of the side surface of the substrate. Therefore, the light extraction efficiency of the LED chip may be further improved.

Still another aspect of the present invention is directed to an LED device, in which a part of the substrate of the LED chip is directly embedded in the heat dissipation base, so the heat generated by the LED chip in operation is effectively conducted out by the heat dissipation base. Therefore, the LED device has an excellent heat dissipation capability.

In one aspect of the present invention, an LED device is provided. The LED device includes a heat dissipation base and an LED chip. The heat dissipation base has a recessed portion. The recessed portion includes an embedded portion and an inclined side surface joined with the embedded portion. The LED chip includes a substrate partially embedded in the embedded portion. The lower region of the side surface of the substrate has a first non-smooth surface, and the first non-smooth surface has an exposed portion protruding from the embedded portion. A bottom edge of the lower region and a bottom surface of the substrate are joined.

According to an embodiment of the present invention, the heat dissipation base includes a metal base, a reflective layer and a ceramic layer. The reflective layer is disposed on the metal base. The ceramic layer is disposed on the reflective layer. The substrate is partially embedded in the ceramic layer.

According to another embodiment of the present invention, the first non-smooth surface has an irregular concave and convex structure or a regular concave and convex structure.

According to still another embodiment of the present invention, the side surface of the substrate further includes: a middle region joined on the lower region and including an area of a half height of the substrate; and an upper region joined on the middle region, in which a top edge of the upper region and a top surface of the substrate are joined. The middle region and/or the upper region have a second non-smooth surface. For example, the second non-smooth surface has an irregular concave and convex structure or a regular concave and convex structure.

According to yet another embodiment of the present invention, the LED chip further includes an epitaxial structure. The epitaxial structure includes a first conductive type semiconductor layer, an active layer and a second conductive type semiconductor layer stacked on the substrate in sequence. The first conductive type semiconductor layer has an exposed portion. A transparent conductive layer is located on the second conductive type semiconductor layer and a first electrode and a second electrode are respectively disposed on the exposed portion of the first conductive type semiconductor layer and the transparent conductive layer.

According to still another embodiment of the present invention, the LED device further includes a first electrode pad, a second electrode pad and two conductive wires. The first electrode pad and the second electrode pad are respectively disposed on the heat dissipation base on two sides of the recessed portion. The two conductive wires respectively connect the first electrode pad and the first electrode and connect the second electrode pad and the second electrode.

According to yet another embodiment of the present invention, the LED device further includes a third electrode pad and a fourth electrode pad disposed on a lower surface of the heat dissipation base. The heat dissipation base has two through holes and the heat dissipation base includes two conductive pins respectively filled in the through holes and two insulating layers respectively isolating the inner side surfaces of the through holes and the conductive pins. The conductive pins respectively electrically connect the first electrode pad and the third electrode pad and electrically connect the second electrode pad and the fourth electrode pad.

According to yet another embodiment of the present invention, an inclined angle between the inclined side surface and the bottom surface ranges from 30° to 60°. In an exemplary embodiment, the inclined angle between the inclined side surface and the bottom surface is substantially 45°.

According to yet another embodiment of the present invention, a height of the substrate protruding from the embedded portion is greater than or equal to the height of the inclined side surface, so that the epitaxial structure is higher than a top of the inclined side surface.

According to yet another embodiment of the present invention, a depth of the part of the substrate embedded in the embedded portion ranges from 5 μm to 10 μm.

By controlling the depth of the substrate of the LED chip embedded into the heat dissipation base and making the non-smooth surface at a side surface of the substrate at least partially exposed from the heat dissipation base, the light extraction efficiency of the LED chip may be increased, thereby further improving the overall luminance of the LED device. Moreover, the design of the LED chip directly embedded in the heat dissipation base may further improve the heat dissipation efficacy of the LED device.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIG. 1 is a sectional view of an LED device according to the related art;

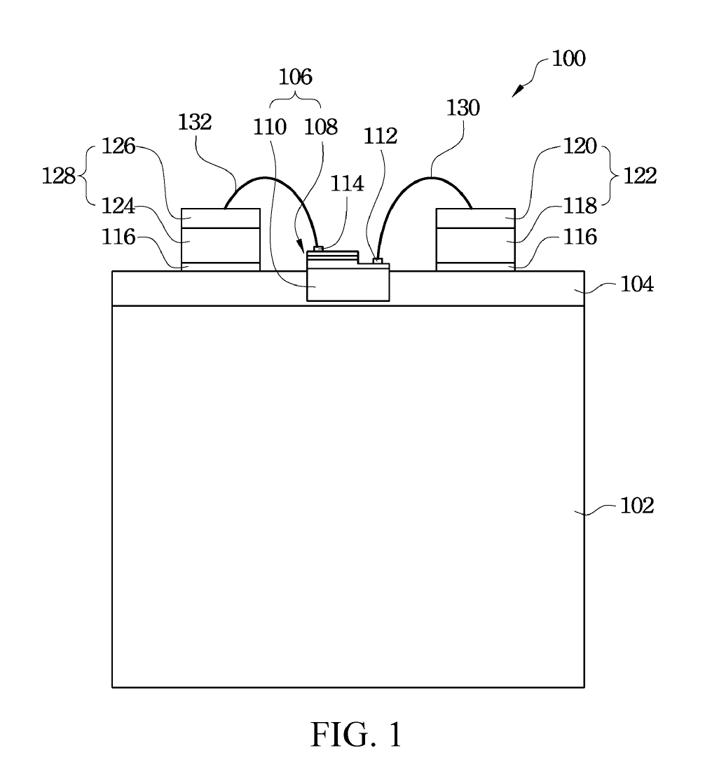

FIG. 2 is a schematic view of a light path of an LED chip according to an embodiment of the present invention;

FIG. 3 is a schematic sectional view of the LED device according to an embodiment of the present invention;

FIG. 4 is a schematic sectional view of the LED device according to another embodiment of the present invention; and

FIG. 5 is a schematic sectional view of the LED device according to still another embodiment of the present invention.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise.

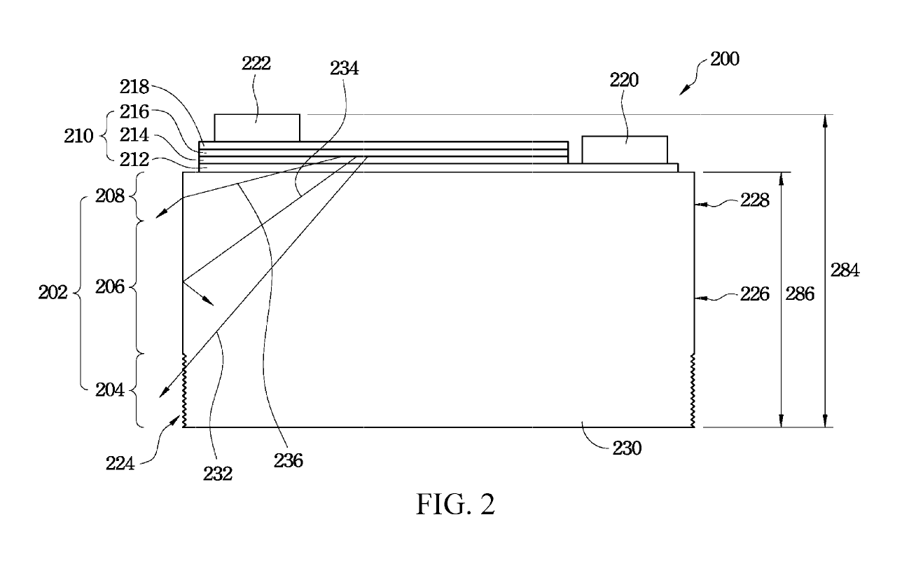

FIG. 2 is a schematic view of a light path of an LED chip according to an embodiment of the present invention. In this embodiment, the LED chip 200 is a horizontal electrode LED structure. However, in other embodiments of the present invention, the LED chip may also be a vertical electrode LED structure.

The LED chip 200 includes a substrate 230, an epitaxial structure 210, a first electrode 220 and a second electrode 222. The substrate 230 may be for example a sapphire substrate. As shown in FIG. 2, the side surface 202 of the substrate 230 may be divided into a lower region 204, a middle region 206 and an upper region 208. The lower region 204 is located on the lower portion of the side surface 202 of the substrate 230, and the bottom edge of the lower region 204 and the bottom surface of the substrate 230 are joined. The top edge of the lower region 204 and the middle region 206 are joined. The top edge of the middle region 206 and the upper region 208 are joined. The middle region 206 includes an area of a half height of the substrate 230, and the top edge of the upper region 208 and the top surface of the substrate 230 are joined. The epitaxial structure 210 is located on the top surface of the substrate 230. In an embodiment, the epitaxial structure 210 includes a first conductive type semiconductor layer 212, an active layer 214 and a second conductive type semiconductor layer 216. In another embodiment, as shown in FIG. 2, the LED chip 200 may further include a transparent conductive layer 218 located on the epitaxial structure 210.

In the fabricating of the epitaxial structure 210, the first conductive type semiconductor layer 212, the active layer 214 and the second conductive type semiconductor layer 216 may be grown on the substrate 230 in sequence for example in an organic metal organic chemical vapor deposition (MOCVD) manner. Hence, the epitaxial structure 210 having the first conductive type semiconductor layer 212, the active layer 214 and the second conductive type semiconductor layer 216 stacked in sequence may be formed. In the present invention, the first conductive type and the second conductive type are opposite. For example, one of the first conductive type and the second conductive type is n-type and the other is p-type. In this exemplary embodiment, the first conductive type is n-type and the second conductive type is p-type. Then, the transparent conductive layer 218 may be formed on the second conductive type semiconductor layer 216 for example in an electron beam evaporation or sputtering manner.

In this embodiment, as the LED chip 200 is a horizontal electrode structure, the transparent conductive layer 218 and the epitaxial structure 210 need mesa definition for example by a lithography and etching process, so as to expose a part of the first conductive type semiconductor layer 212. As shown in FIG. 2, the first electrode 220 and the second electrode 222 are respectively disposed on the exposed portion of the first conductive type semiconductor layer 212 of the epitaxial structure 210 and a part of the transparent conductive layer 218.

The inventor finds that when the LED chip 200 is lit, the part with the highest luminance is the part of the epitaxial structure 210 and is also a primary part that contributes to the luminance. The part with the second highest luminance is the lower part of the substrate 230 of the LED chip 200 and is also a secondary part that contributes to the luminance. The light is emitted from the lower region 204 at the side surface 202 of the substrate 230. The part with the third highest luminance is the upper part where the substrate 230 and the epitaxial structure 210 are joined and is the third part that contributes to the luminance. The light is emitted from the upper region 208 at the side surface 202 of the substrate 230. However, it should be noted that nearly no light is emitted from the middle part of the substrate 230. The situation of the light emission from the middle part of the substrate 230 may be observed from the middle region 206 of the side surface 202 of the substrate 230. It can be seen from FIG. 2 that the middle part of the substrate 230 accounts for a major part of the entire substrate 230 but contributes to the least luminance.

The inventor analyzes the observation result and finds that the lower region 204 of the side surface 202 of the substrate 230 has a non-smooth surface 224, so the non-smooth surface 224 has an irregular concave and convex structure. The inventor further analyzes the result and finds that in the fabricating of the chip scribing/breaking, the bottom of the substrate 230 is cut by a laser to form a partial slot and after the scribing/breaking procedure, an irregular laser melted surface is formed on the lower region 204 of the side surface 202 in the embodiment of the present invention. On the other hand, the upper region 208 and the middle region 206 of the side surface 202 of the substrate 230 respectively have smooth surfaces 228 and 226 generated after scribing/breaking.

In an embodiment, the non-smooth surface 224 of the lower region 204 of the substrate 230 may be an irregular concave and convex structure. In another embodiment, the non-smooth surface 224 of the lower region 204 of the substrate 230 may be a regular concave and convex structure. In this embodiment, the non-smooth surface 224 having the irregular concave and convex structure may be generated by a scribing tool such as laser during the scribing/breaking process. However, the non-smooth surface 224 having the irregular concave and convex structure may also be formed by a patterning technique such as the lithography and etching process. On the other hand, the non-smooth surface 224 having regular concave and convex structure may also be formed by the patterning technique such as the lithography and etching process.

Therefore, it can be seen from the light path in FIG. 2 that when the light 236 emitted by the active layer 214 is emitted on the upper region 204 of the side surface 202 of the substrate 230, the incident angle does not exceed the critical angle, so the light 236 may still be emitted to the outside. When the light 234 emitted by the active layer 214 is emitted on the middle region 206 of the side surface 202 of the substrate 230, as the incident angle exceeds the critical angle, the light 234 will be totally reflected back into the substrate 230 and cannot be emitted to the outside. On the other hand, when the light 232 emitted by the active layer 214 is emitted on the lower region 204 of the side surface 202 of the substrate 230, as the lower region 204 has the non-smooth concave and convex surface, the total reflection surface is ruined and the light 232 may still be effectively extracted from the lower region 204 of the side surface 202.

In view of the above discovery, to prevent the light 232 originally extracted from the lower region 204 of the side surface 202 of the substrate 230 from being confined in the heat dissipation base disposed on LED chip 200, a novel LED device architecture is proposed.

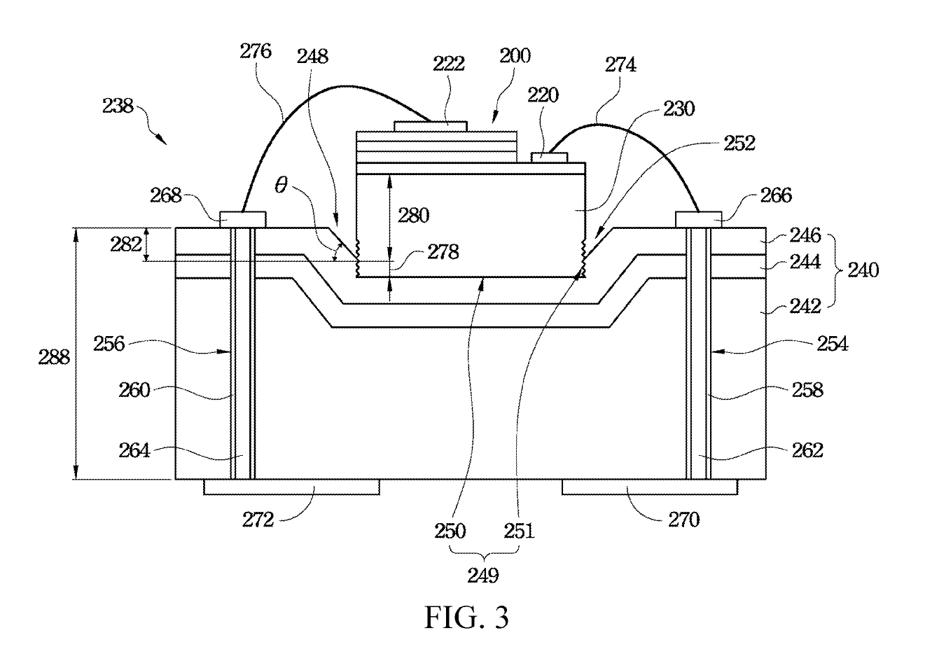

Referring to FIGS. 2 and 3 together, FIG. 3 is a schematic sectional view of the LED device according to an embodiment of the present invention. In this embodiment, the LED device 238 includes a heat dissipation base 240 and an LED chip 200. The LED chip 200 is embedded in the heat dissipation base 240.

In an embodiment, the heat dissipation base 240 may include a metal base 242, a reflective layer 244 and a ceramic layer 246. The reflective layer 244 is covered on the surface of the metal base 242 and the ceramic layer 246 is covered on the reflective layer 244. A material of the metal base 242 may be for example copper, copper alloy, ferrum/nickel alloy, nickel, tungsten, molybdenum or any alloy thereof. A material of the reflective layer 244 may be for example silver/aluminum stack structure. A material of the ceramic layer 246 preferably is the transparent material, for example, aluminum oxide.

To improve the luminance of the LED device 238, the heat dissipation base 240 has a recessed portion 248. The recessed portion 248 includes an embedded portion 249 and an inclined side surface 252 joined with the embedded portion 249. The embedded portion 249 includes a bottom surface 250 and an embedded side surface 251. Therefore, the surface where the recessed portion 248 of the heat dissipation base 240 is located may have a cup structure.

The LED chip 200 is disposed in the recessed portion 248 of the heat dissipation base 240, and the substrate 230 of the LED chip 200 is partially embedded in the embedded portion 249 of the recessed portion 248. That is to say, a part of the substrate 230 is embedded in the embedded side surface 251 and the bottom surface 250 of the ceramic layer 246. By embedding a part of the substrate 230 of the LED chip 200 in the ceramic layer 246, the ceramic layer 246 may be used to deliver the heat generated by the LED chip 200 in operation and the heat is further downwardly conducted to the metal base 242 and then dissipated to the outside.

Furthermore, as shown in FIG. 2, to prevent the light 232 that can be extracted from the lower region 204 of the side surface 202 of the substrate 230 from being confined in the heat dissipation base 240, the depth of the substrate 230 embedded in the heat dissipation base 240 is controlled in this embodiment, so that the non-smooth surface 224 of the lower region 204 of the side surface 202 is not completely embedded in heat dissipation base 240 and has an exposed portion protruding from the embedded portion 249 of the recessed portion 248. In other words, the height of the embedded side surface 251 of the embedded portion 249 is smaller than that of the lower region 204.

For example, referring to FIGS. 2 and 3 together, if the height 284 of the overall LED chip 200 is about 150 μm, in which the height 286 of the substrate 230 is about 140 μm to about 145 μm and the height of the lower region 204 of the substrate 230 is about 20 μm to about 35 μm. The height 288 of the heat dissipation base 240 is about 200 μm. At this time, the depth of the substrate 230 of the LED chip 200 embedded in the ceramic layer 246 of the heat dissipation base 240 is about 5 μm to about 10 μm, that is, the height of the embedded side surface 251 is about 5 μm to about 10 μm. In this manner, the major part of the lower region 204 of the side surface 202 of the substrate 230 is still protruded from the embedded portion 249 of the recessed portion 248 of the heat dissipation base 240. Therefore, the light emitted by the active layer 214 may still be emitted to the outside by the epitaxial structure 210, the transparent conductive layer 218, and the upper region 208 and the major part of the lower region 204 of the side surface 202 of the substrate 230. Although the light emitted by the active layer 214 is emitted to the bottom surface of the substrate 230 embedded in the ceramic layer 246, the light may still be easily reflected by the ceramic layer 246 and/or the reflective layer 244 and leave the embedded part of the substrate 230, and then is emitted through the upper side of the LED chip 200 or the non-embedded region of the side surface 202. The light emitted on the bottom of the substrate 230 of the LED chip 200 passing through the transparent ceramic layer 246 may also be reflected by the reflective layer 244 below to be emitted to the outside. Therefore, the overall luminance of the LED device 238 may be improved.

In an exemplary embodiment, the depth 278 of the part of the substrate 230 of the LED chip 200 embedded in the embedded portion 249 of the recessed portion 248 may for example ranges from about 5 μm to about 10 μm. Furthermore, to prevent the heat dissipation base 240 from blocking the side light of the active layer 214, the height 280 obtained by subtracting the depth 278 of the substrate 230 embedded in the embedded portion 249 of the recessed portion 248 from the height 286 of the substrate 230 is the height of the substrate 230 protruding from the embedded portion 249, and preferably is greater than or equal to the height 282 of the inclined side surface 252 of the recessed portion 248. In this manner, the epitaxial structure 210 is higher than the top of the inclined side surface 252, thereby increasing the light extraction efficiency of the LED device 238. In an embodiment, the inclined angle θ between the inclined side surface 252 and the bottom surface 250 may for example range from 30° to 60°, and preferably 45° for reflecting the side light of the LED chip 200 upwards.

In this embodiment, by embedding the LED chip 200 in the heat dissipation base 240 and exposing a part of the non-smooth surface 224 of the lower region 204 of the side surface 202 of the substrate 230 from the embedded portion 249 of the recessed portion 248, it is verified by the experiment that the luminous efficiency of the LED chip 210 increases by about more than 10%, thus effectively improving the overall luminance of the LED device 238. Furthermore, the heat dissipation base 240 may effectively remove the heat generated by the LED chip 200 in operation, thus greatly improving the heat dissipation efficacy of the LED device 238.

In an embodiment, as shown in FIG. 3, the LED device 238 further includes two electrode pads 266 and 268. The two electrode pads 266 and 268 are respectively disposed on the heat dissipation bases on two sides of the recessed portion 248 of the heat dissipation base 240. In an exemplary embodiment, the electrode pads 266 and 268 are respectively disposed on two opposite sides of the recessed portion 248. Furthermore, in the LED device 238, the conductive wires 274 and 276 respectively connect the electrode 220 and the electrode pad 266 and connect the electrode 222 and the electrode pad 268 of the LED chip 200, thereby electrically connecting the electrode 220 and the electrode pad 266 and connecting the electrode 222 and the electrode pad 268 in the wire bonding process.

In an embodiment, two more conductive wires are used to connect the above two electrode pads 266 and 268 respectively to the two electrodes of an external power source. However, in this exemplary embodiment, the LED device 238 and the external power source are electrically connected by using a surface mount technology (SMT) process. As shown in FIG. 3, the heat dissipation base 240 of this embodiment further includes two through holes 254 and 256. The two through holes 254 and 256 respectively extend downwardly from the bottom surfaces of the electrode pads 266 and 268 to the lower surface of the heat dissipation base 240 and thus penetrating the entire heat dissipation bases 240.

The inner side surfaces of the through holes 254 and 256 are respectively covered by the insulating layers 258 and 260. A material of the insulating layers 258 and 260 may be for example metal oxide, silicon dioxide or silicon nitride. The heat dissipation base 240 may also include two conductive pins 262 and 264. The two conductive pins 262 and 264 are respectively filled in the through holes 254 and 256 and the side surfaces of the conductive pins 262 and 264 are respectively encapsulated by the insulating layers 258 and 260. Therefore, the insulating layers 258 and 260 may respectively isolate the inner side surface of the through hole 254 and the conductive pin 262, and isolate the inner side surface of the through hole 256 and the conductive pin 264. The conductive pins 262 and 264 may be formed by a conductive material, for example a metal material such as copper or gold and any alloy thereof.

The LED device 238 includes two electrode pads 270 and 272. The two electrode pads 270 and 272 are disposed on the lower surface of the heat dissipation base 240, and respectively shield the opening on one end of the through hole 254 and the opening on one end of the through holes 256, and are respectively electrically connected to one end of the conductive pin 262 and one end of the conductive pin 264. In this manner, the conductive pins 262 and 264 may respectively electrically connect the electrode pads 266 and 270 and the electrode pads 268 and 272 on two opposite surfaces of the heat dissipation base 240. Therefore, the LED device 238 may be fixed on the package base or circuit board (not shown) by for example the SMT process through the electrode pads 270 and 272, and is then electrically connected to the external power source by the package base or circuit board.

Therefore, in the LED device 238, the LED chip 200 may be electrically connected to the two electrodes of the external power source respectively through the two electrodes 220 and 222 thereon via the conductive wires 274 and 276, the electrode pads 266 and 268, the conductive pins 262 and 264 and the electrode pads 270 and 272. In this manner, the external power source may successfully input the power to the LED chip 200, so that the LED chip 200 emits the light.

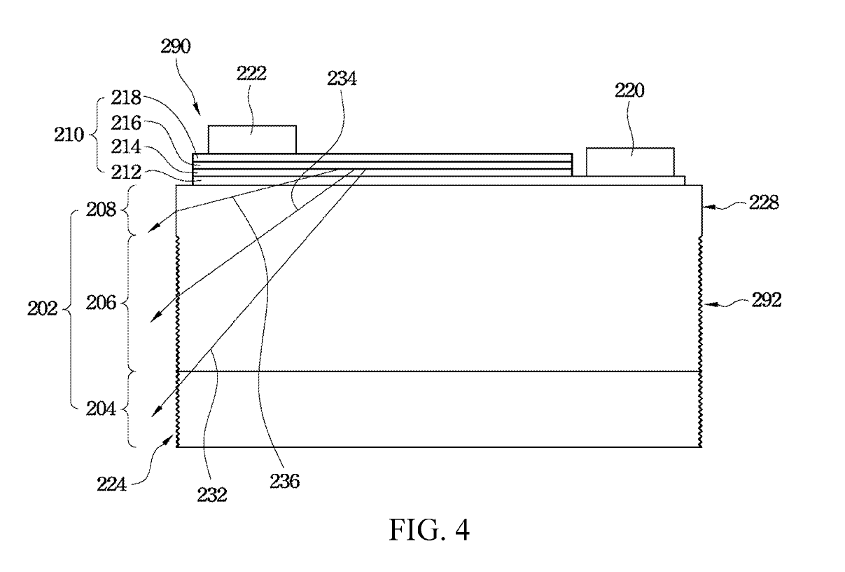

The non-smooth surface of the side surface of the LED chip of the present invention may be not limited to be disposed on the lower region. FIG. 4 is a schematic sectional view of the LED device according to another embodiment of the present invention. The architecture of the LED chip 290 of this embodiment is substantially identical to the LED chip 200 of the above embodiment, and the difference lies in that in the LED chip 290, the lower region 204 of the side surface 202 has a non-smooth surface 224, and the middle region 206 joined with the lower region 204 also has a non-smooth surface 292.

In an embodiment, the non-smooth surface 292 of the middle region 206 of the substrate 230 may be the irregular concave and convex structure. In another embodiment, the non-smooth surface 292 may also be the regular concave and convex structure. In this embodiment, the non-smooth surface 292 having the irregular concave and convex structure may also be the melted surface formed by a scribing tool such as laser. However, the non-smooth surface 292 having the irregular concave and convex structure may be formed by the patterning technique such as the lithography and etching process. On the other hand, the non-smooth surface 292 having the regular concave and convex structure may be formed by the patterning technique such as the lithography and etching process.

In the LED chip 290, as the middle region 206 of the side surface 202 of the substrate 230 has the non-smooth surface 292, the light 234 emitted by the active layer 214 is emitted to the outside through the middle region 206 of the side surface 202 of the substrate 230. In this manner, the light extraction efficiency of the LED chip 290 may be further increased.

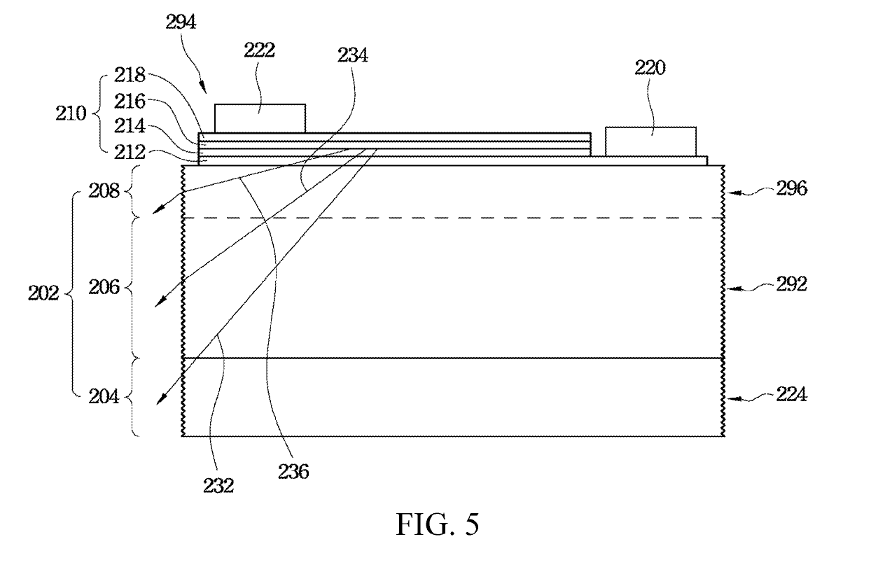

FIG. 5 is a schematic sectional view of the LED device according to still another embodiment of the present invention. The architecture of the LED chip 294 of this embodiment is substantially identical to the architecture of the LED chip 290 of the above embodiment, and the difference lies in that in the LED chip 294, the lower region 204 and the middle region 206 of the side surface 202 respectively have the non-smooth surfaces 224 and 292, and the upper region 208 joined with the middle region 206 also has the non-smooth surface 296.

In an embodiment, the non-smooth surface 296 of the upper region 208 of the substrate 230 may also be the irregular concave and convex structure. In another embodiment, the non-smooth surface 296 may also be the regular concave and convex structure. In this embodiment, the non-smooth surface 296 having the irregular concave and convex structure may be the melted surface formed by a scribing tool such as laser. However, the non-smooth surface 296 having the irregular concave and convex structure may be formed by the patterning technique such as the lithography and etching process. On the other hand, the non-smooth surface 296 having the regular concave and convex structure may be formed by the patterning technique such as the lithography and etching process.

In the LED chip 294, as the middle region 206 and the upper region 208 of the side surface 202 of the substrate 230 respectively have the non-smooth surfaces 292 and 296, the light 234 and 236 emitted by the active layer 214 are respectively emitted to the outside by the middle region 206 and the upper region 208 of the side surface 202 of the substrate 230. In this manner, the light extraction efficiency of the LED chip 294 may be further increased.

It should be noted that the non-smooth surface area of the side surface of the substrate of the LED chip of the present invention may be located on the lower region, the middle region and/or the upper region of the side surface of the substrate. For example, in an embodiment, the non-smooth surface area of the side surface of the substrate may be located on the lower region and the upper region of the side surface of the substrate at the same time. Therefore, in the present invention, the configuration of the non-smooth surface is not limited to the above embodiment.

It may be known from the above embodiment that the present invention has the following advantage. As the non-smooth surface of the side surface of the substrate of the LED chip of the LED device is not completely embedded in the heat dissipation base below, the exposed portion of the embedded portion protrudes from the embedded heat dissipation base. Therefore, the light emitted downwardly by the epitaxial structure may be successfully emitted to the outsides by the side surface of the substrate. Therefore, the overall luminance of the LED device can be effectively improved.

It may be known from the above embodiment that the present invention has another advantage. The lower region, the middle region and/or the upper region of the side surface of the substrate of the LED chip of the LED device have the non-smooth surface, so the light emitted by the epitaxial structure may be emitted through the middle region and/or the upper region of the side surface of the substrate. Therefore, the light extraction efficiency of the LED chip may be further improved.

It may be known from the above embodiment that the present invention has still another advantage that a part of the substrate of the LED chip of the LED device is directly embedded in the heat dissipation base, so the heat generated by the LED chip in operation is effectively conducted out by the heat dissipation base. Therefore, the LED device has an excellent heat dissipation capability.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments are chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A light-emitting diode (LED) device, comprising:
a heat dissipation base with a recessed portion, wherein the recessed portion comprises an embedded portion and an inclined side surface joined with the embedded portion; and
an LED chip with a substrate partially embedded in the embedded portion, wherein a lower region of a side surface of the substrate has a first non-smooth surface, and the first non-smooth surface has an exposed portion protruding from the embedded portion, and a bottom edge of the lower region and a bottom surface of the substrate are joined.

2. The LED device according to claim 1, wherein the heat dissipation base comprises:
a metal base;
a reflective layer, disposed on the metal base; and
a ceramic layer, disposed on the reflective layer, wherein the substrate is partially embedded in the ceramic layer.

3. The LED device according to claim 2, wherein a material of the metal base comprises copper, copper alloy, ferrum/nickel alloy, nickel, tungsten, molybdenum or any alloy thereof.

4. The LED device according to claim 2, wherein a material of the ceramic layer comprises a transparent material.

5. The LED device according to claim 2, wherein a material of the ceramic layer comprises aluminum oxide.

6. The LED device according to claim 1, wherein the first non-smooth surface has an irregular concave and convex structure.

7. The LED device according to claim 1, wherein the first non-smooth surface has a regular concave and convex structure.

8. The LED device according to claim 1, wherein the side surface of the substrate further comprises:
a middle region, joined on the lower region and having an area of a half height of the substrate; and
an upper region, joined on the middle region, wherein a top edge of the upper region and a top surface of the substrate are joined, and the middle region and/or the upper region have a second non-smooth surface.

9. The LED device according to claim 8, wherein the second non-smooth surface has an irregular concave and convex structure.

10. The LED device according to claim 8, wherein the second non-smooth surface has a regular concave and convex structure.

11. The LED device according to claim 1, wherein the LED chip further comprises:
an epitaxial structure, having a first conductive type semiconductor layer, an active layer and a second conductive type semiconductor layer stacked on the substrate in sequence, wherein the first conductive type semiconductor layer has an exposed portion;
a transparent conductive layer, located on the second conductive type semiconductor layer; and
a first electrode and a second electrode, respectively disposed on the exposed portion of the first conductive type semiconductor layer and the transparent conductive layer.

12. The LED device according to claim 11, further comprising:
a first electrode pad and a second electrode pad, respectively disposed on the heat dissipation bases on two sides of the recessed portion; and
two conductive wires, respectively connecting the first electrode pad and the first electrode and connecting the second electrode pad and the second electrode.

13. The LED device according to claim 12, further comprising:
a third electrode pad and a fourth electrode pad disposed on a lower surface of the heat dissipation base,
wherein the heat dissipation base has two through holes, and the heat dissipation base comprises two conductive pins respectively filled in the through holes and two insulating layers respectively isolating inner side surfaces of the through holes and the conductive pins, the conductive pins electrically connect the first electrode pad and the third electrode pad and electrically connect the second electrode pad and the fourth electrode pad respectively.

14. The LED device according to claim 13, wherein a material of the insulating layers comprises metal oxide, silicon dioxide or silicon nitride.

15. The LED device according to claim 13, wherein a material of the conductive pins comprises copper, gold or an alloy thereof.

16. The LED device according to claim 1, wherein an inclined angle between the inclined side surface and the bottom surface ranges from 30° to 60°.

17. The LED device according to claim 1, wherein an inclined angle between the inclined side surface and the bottom surface is substantially 45°.

18. The LED device according to claim 1, wherein a height of the substrate protruding from the embedded portion is greater than or equal to a height of the inclined side surface, so that the epitaxial structure is higher than the top of the inclined side surface.

19. The LED device according to claim 1, wherein a depth of the part of the substrate embedded in the embedded portion ranges from 5 μm to 10 μm.

20. The LED device according to claim 1, wherein a height of the lower region of the substrate ranges from 20 μm to 35 μm.
